(19) United States
(12) Patent Application Publication
(10) Pub. No.: US 2025/0176099 A1
(43) Pub. Date: May 29, 2025

(54) PRINTED CIRCUIT BOARD

(71) Applicant: SAMSUNG ELECTRO-MECHANICS CO., LTD., Suwon-si (KR)

(72) Inventors: Tae Hong MIN, Suwon-si (KR); Sang Hoon KIM, Suwon-si (KR)

(73) Assignee: SAMSUNG ELECTRO-MECHANICS CO., LTD., Suwon-si (KR)

(21) Appl. No.: 18/829,696

(22) Filed: Sep. 10, 2024

(30) Foreign Application Priority Data
Nov. 23, 2023 (KR) 10-2023-0164535

(51) Int. Cl. H05K 1/02; H05K 1/03; H05K 1/11

(52) U.S. Cl. CPC H05K 1/0298; H05K 1/0306; H05K 1/115; H05K 2201/096

(57) ABSTRACT

A printed circuit board includes an inorganic substrate, a through-via passing through the inorganic substrate, a first insulating layer covering at least a portion of an external surface of the inorganic substrate, a second insulating layer disposed on an upper surface of each of the inorganic substrate and the first insulating layer, a third insulating layer disposed on a lower surface of each of the inorganic substrate and the first insulating layer, a first wiring layer disposed on an upper surface of the second insulating layer, and a second wiring layer disposed on a lower surface of the third insulating layer. The inorganic substrate includes silicon or ceramic. The inorganic substrate has an upper end and a lower end having different widths, in cross-section.

### CROSS-REFERENCE TO RELATED APPLICATION(S)

This application claims benefit of priority to Korean Patent Application No. 10-2023-0164535 filed on Nov. 23, 2023 in the Korean Intellectual Property Office, the disclosure of which is incorporated herein by reference in its entirety.

### TECHNICAL FIELD

The present disclosure relates to a printed circuit board.

As the market has recently changed from the existing mobile device-centered business to high-capacitance servers, an amount of data has been rapidly increasing and servers, networks, and storage have also been more rapidly increasing. Accordingly, new high-multilayer structure boards have been expanding. Accordingly, a fan-out multichip module (FOMCM), a fan-out embedded bridge (FOEB), an embedded multi-die interconnect bridge (EMIB), and the like have been developed. In order to respond to the high-capacitance server market, many companies are attempting to develop board labels with 2.1D as a final goal. However, layers of a printed circuit board according to the related art may basically have a high multilayer structure, and a microcircuit may be applied to the printed circuit board. As a result, there are limitations in solving issues in terms of actual yield and costs.

### SUMMARY

An aspect of the present disclosure provides a printed circuit board including a high-density microcircuit that may be formed at high yield and low cost.

Another aspect of the present disclosure provides a printed circuit board having excellent warpage control characteristics.

According to an aspect of the present disclosure, there is provided a printed circuit board. First, in an inorganic substrate including silicon or ceramic, the inorganic substrate having a through-via may be cut to form a plurality of core portions having a tapered external surface. Subsequently, the plurality of core portions may be respectively disposed in a plurality of through-portions of a frame. After each of the plurality of through-portions is filled with a first insulating layer, the frame may be cut to form a plurality of unit boards. Subsequently, an insulating layer and a wiring layer may be formed on the unit board to manufacture a multilayer printed circuit board.

For example, the printed circuit board according to an aspect of the present disclosure may include an inorganic substrate, a through-via passing through the inorganic substrate, a first insulating layer covering at least a portion of an external surface of the inorganic substrate, a second insulating layer disposed on an upper surface of each of the inorganic substrate and the first insulating layer, a third insulating layer disposed on a lower surface of each of the inorganic substrate and the first insulating layer, a first wiring layer disposed on an upper surface of the second insulating layer, and a second wiring layer disposed on a lower surface of the third insulating layer. The inorganic substrate may include silicon or ceramic. The inorganic substrate may have an upper end and a lower end having different widths, in cross-section.

According to example embodiments of the present disclosure, a printed circuit board may include a high-density microcircuit that may be manufactured at high yield and low cost.

According to example embodiments of the present disclosure, a printed circuit board may have excellent warpage control characteristics.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic block diagram of an example of an electronic device system;

FIG. 2 is a schematic perspective view of an example of an electronic device;

FIG. 3 is a schematic cross-sectional view of an example of a printed circuit board;

FIGS. 4A to 4D are schematic cross-sectional views of example processes of a method of manufacturing the printed circuit board in FIG. 3;

FIGS. 5A and 5B are schematic perspective views of example processes of a case in which a plurality of core portions, provided on a unit basis, are disposed on a frame having a plurality of through-portions;

FIGS. 6 and 7 are schematic cross-sectional views of modifications of the printed circuit board in FIG. 3, respectively;

FIG. 8 is a schematic cross-sectional view of another example of a printed circuit board;

FIGS. 9 and 10 are schematic cross-sectional views of modifications of the printed circuit board in FIG. 8, respectively;

FIG. 11 is a schematic cross-sectional view of another example of a printed circuit board;

FIGS. 12 and 13 are schematic cross-sectional views of modifications of the printed circuit board in FIG. 11, respectively;

FIG. 14 is a schematic cross-sectional view of another example of a printed circuit board;

FIGS. 15 and 16 are schematic cross-sectional views of modifications of the printed circuit board in FIG. 14, respectively;

FIG. 17 is a schematic cross-sectional view of another example of a printed circuit board;

FIGS. 18 and 19 are schematic cross-sectional views of modifications of the printed circuit board in FIG. 17, respectively;

FIG. 20 is a schematic cross-sectional view of another example of a printed circuit board; and

FIGS. 21 and 22 are schematic cross-sectional views of modifications of the printed circuit board in FIG. 20, respectively.

### DETAILED DESCRIPTION

Hereinafter, example embodiments of the present disclosure are described with reference to the accompanying drawings. The shapes and sizes of elements in the drawings may be exaggerated or reduced for clearer description.

### Electronic Device

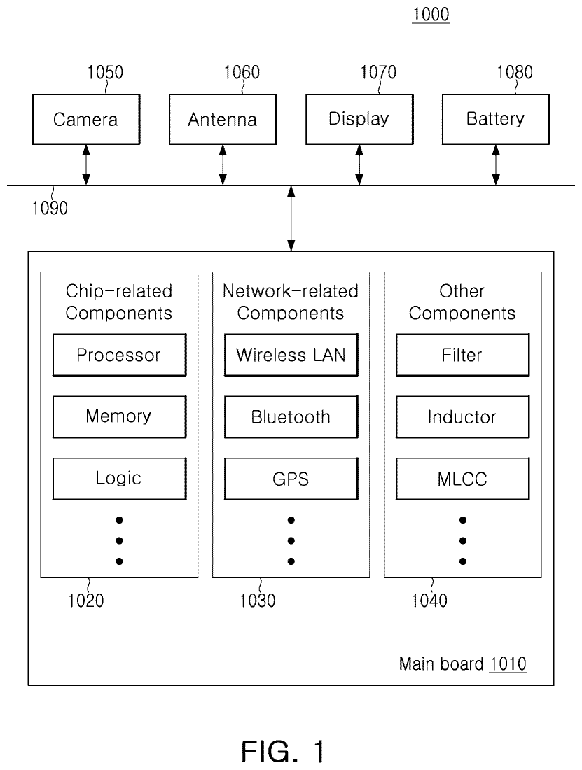

FIG. 1 is a schematic block diagram illustrating an example of an electronic device system.

Referring to FIG. 1, an electronic device 1000 may accommodate a mainboard 1010. The mainboard 1010 may include chip-related components 1020, network-related components 1030, other components 1040, or the like, physically or electrically connected thereto. Such components may be connected to other components to be described below to form various signal lines 1090.

The chip-related components 1020 may include a memory chip such as a volatile memory (for example, a dynamic random access memory (DRAM)), a non-volatile memory (for example, a read only memory (ROM)), a flash memory, or the like, an application processor chip such as a central processor (for example, a central processing unit (CPU)), a graphics processor (for example, a graphics processing unit (GPU)), a digital signal processor, a cryptographic processor, a microprocessor, a microcontroller, or the like, and a logic chip such as an m analog-to-digital converter, an application-specific integrated circuit (ASIC), or the like, or the like. However, the chip-related components 1020 are not limited thereto, and may include other types of chip-related components. In addition, the chip-related components 1020 may be combined with each other. The chip-related components 1020 may be in the form of a package including the above-described chip or electronic component.

The network-related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth®, 3G, 4G, and 5G protocols, and any other wireless and wired protocols, designated after the above-described protocols. However, the network-related components 1030 are not limited thereto, and may also include a variety of other wireless or wired standards or protocols. In addition, the network-related components 1030 may be combined with each other, together with the chip-related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, and may also include passive components used for various other purposes, or the like. In addition, other components 1040 may be combined with each other, together with the chip-related components 1020 or the network-related components 1030 described above.

Depending on a type of the electronic device 1000, the electronic device 1000 may include other components that may or may not be physically or electrically connected to the mainboard 1010. The other components may include, for example, a camera 1050, an antenna 1060, a display 1070, a battery 1080, and the like. However, the other components are limited thereto, and may be an audio codec, a video codec, a power amplifier, a compass, an accelerometer, a gyroscope, a speaker, a mass storage unit (for example, a hard disk drive), a compact disk (CD), a digital versatile disk (DVD), or the like. In addition, the other components may also include other components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device to process data.

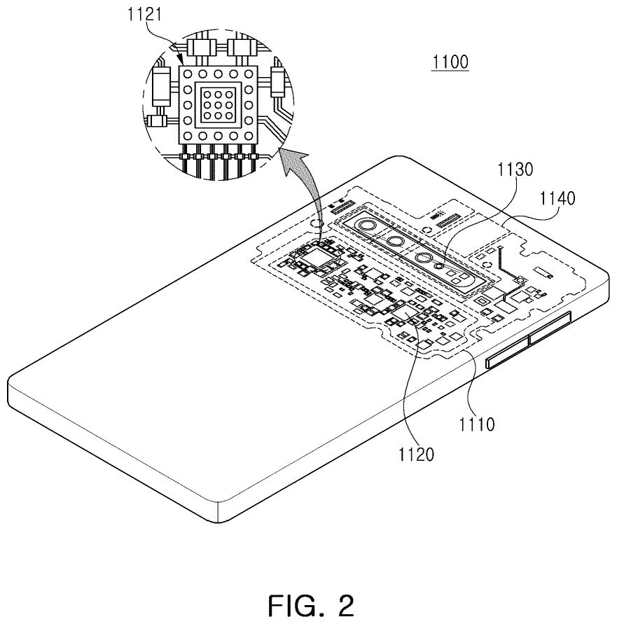

FIG. 2 is a schematic perspective view illustrating an example of an electronic device.

Referring to FIG. 2, an electronic device may be, for example, a smartphone 1100. The motherboard 1110 may be accommodated in the smartphone 1100, and various electronic components 1120 may be physically and/or electrically connected to the motherboard 1110. In addition, other electronic components that may or may not be physically and/or electrically connected to the motherboard 1110 may be accommodated therein, such as a camera module 1130 and/or a speaker 1140. A portion of the electronic components 1120 may be the above-described chip related components, for example, a component package 1121, but the present disclosure is not limited thereto. The component package 1121 may be in the form of a printed circuit board on which electronic components including active components and/or passive components are surface-mounted. The electronic device is not necessarily limited to the smartphone 1100, and may be other electronic devices as described above.

### Printed Circuit Board

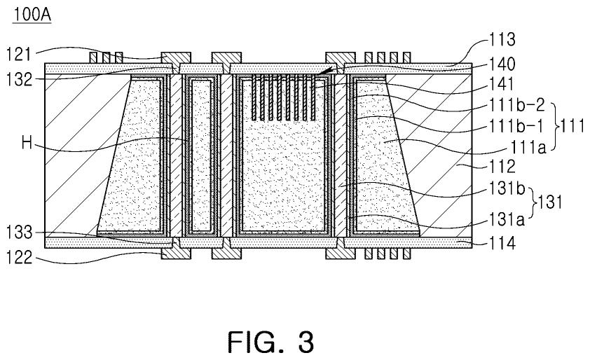

FIG. 3 is a schematic cross-sectional view of an example of a printed circuit board.

Referring to FIG. 3, a printed circuit board 100A according to some example embodiments may include a core layer 111, a first insulating layer 112 covering at least a portion of an external surface of the core layer 111, a through-via 131 passing through the core layer 111, a second insulating layer 113 disposed on an upper side of each of the core layer 111 and the first insulating layer 112, a third insulating layer 114 disposed on a lower side of each of the core layer 111 and the first insulating layer 112, a first wiring layer 121 disposed on an upper surface of the second insulating layer 113, a second wiring layer 122 disposed on a lower surface of the third insulating layer 114, a first connection via 132 passing through the second insulating layer 113 to connect the through-via 131 and the first wiring layer 121 to each other, and a second connection via 133 passing through the third insulating layer 114 to connect the through-via 131 and the second wiring layer 122 to each other. The printed circuit board 100A may further include a capacitor 140, including a plurality of conductive trenches 141 each passing through a portion of the core layer 111, as necessary.

The core layer 111 may include an inorganic substrate 111a. In this case, the inorganic substrate 111a may include silicon or ceramic. Accordingly, the inorganic substrate 111a may basically have excellent flatness, which may be more advantageous for a high-density circuit having a fine pitch. In addition, the inorganic substrate 111a, having higher rigidity, may be more advantageous in warpage control, as compared to a general organic board. In addition, the core layer 111 may be provided on a basis of a unit in which the through-via 131 is formed, and may have an upper end and a lower end having different width, in cross-section. In addition, for example, the inorganic substrate 111a may have an upper end having a width, narrower than a width of a lower end thereof, in cross-section. An external surface of the inorganic substrate 111a may be substantially inclined. For example, the external surface of the inorganic substrate 111a may have a substantially tapered shape. In addition, the external surface of the inorganic substrate 111a may be covered by the first insulating layer 112 and may not be externally exposed. In addition, the second insulating layer 113 and the third insulating layer 114 may be laminated on the core layer 111, for example, the inorganic substrate 111a and the first insulating layer 112, thereby further increasing flatness. Accordingly, it may be more advantageous to form a high-density microcircuit circuit having a fine pitch. For example, a network board or a high-performance package board may be more easily provided using the printed circuit board 100A. For example, the printed circuit board 100A may be used as a 2.xD-level flip chip board (FCB).

The core layer 111 may further include inorganic insulating films 111b-1 and 111b-2 covering at least a portion of each of an upper surface and a lower surface of the inorganic substrate 111a. For example, the inorganic substrate 111a may be a silicon board, and the inorganic insulating films 111b-1 and 111b-2 may include an oxide film 111b-1 and/or a nitride film 111b-2. As a non-limiting example, the core layer 111 may include a silicon board as the inorganic substrate 111a, and may include an oxide film 111b-1 disposed on the inorganic substrate 111a, the oxide film 111b-1 including SiO₂ or the like, and a nitride film 111b-2 disposed on the inorganic oxide film 111b-1, the nitride film 111b-2 including SiN or the like. The inorganic substrate 111a may have a through-hole H in which the through-via 131 is disposed, and the inorganic insulating films 111b-1 and 111b-2 may extend to a space between the inorganic substrate 111a and the through-via 131 to cover at least a portion of a wall surface of the through-hole H. As described, the inorganic insulating films 111b-1 and 111b-2 may be formed on the inorganic substrate 111a, thereby protecting a surface of the inorganic substrate 111a, providing an insulating region, and preventing a short circuit in the through-via 131.

The through-via 131 may include a first metal layer 131a disposed on the inorganic insulating films 111b-1 and 111b-2 in the through-hole H, and a second metal layer 131b filling at least a portion of the through-hole H, on the first metal layer 131a. The first metal layer 131a may be a seed layer, and may be formed, for example, using electroless plating or sputtering. The first metal layer 131a may include titanium (Ti), copper (Cu), or the like, but the present disclosure is not limited thereto. The second metal layer 131b may include a plating layer, and may be formed, for example, using electrolytic plating. The second metal layer 131b may include copper (Cu), but the present disclosure is not limited thereto. The second metal layer 131b may have a width wider than that of the first metal layer 131a, in cross-section. The through-via 131 may be, for example, a through silicon via (TSV), or the like, and may be formed in the core layer 111 to provide an electrical connection path between the upper and lower sides of the core layer 111. The through-via 131 may have a pillar shape, in cross-section. For example, a side surface of the through-via 131 may be substantially perpendicular to an upper surface and a lower surface of the through-via 131, but the present disclosure is not limited thereto, and may have an hourglass shape, as necessary.

The first to third insulating layers 112, 113, and 114 may each include an organic insulating material. For example, the first insulating layer 112 may include underfill resin (UR), an epoxy molding compound (EMC), a thermal interface material (TIM), or the like, depending on the required properties. In addition, the second and third insulating layers 113 and 114 may include a prepreg (PPG), an Ajinomoto build-up film (ABF), or the like for wiring formation. Accordingly, the first insulating layer 112 may have an interlayer boundary with each of the second and third insulating layers 113 and 114. Before the second and third insulating layers 113 and 114 are formed, the first insulating layer 112 may be flattened together with the core layer 111, such that an upper surface and a lower surface of the first insulating layer 112 may be substantially coplanar with an upper surface and a lower surface of the core layer 111, respectively. The first insulating layer 112 may include the same organic insulating material as those of the second insulating layer 113 and/or the third insulating layer 114, as necessary. In this case, the first insulating layer 112 may be integrated with the second insulating layer 113 and/or the third insulating layer 114, and thus may not have an interlayer boundary with the second insulating layer 113 and/or the third insulating layer 114. For example, when the second insulating layer 113 and/or the third insulating layer 114 are formed, the first insulating layer 112 may also be formed.

The first and second connection vias 132 and 133 may be in direct contact with the through-via 131. For example, the first connection via 132 may be in direct contact with the upper surface of the through-via 131. In addition, the second connection via 133 may be in direct contact with the lower surface of the through-via 131. For example, it may be difficult to secure adhesion to the upper surface and the lower surface of the core layer 111, such that a wiring layer, including a pad pattern or the like, may not be formed. The first and second connection vias 132 and 133 may have a tapered shape directions opposite from each other. For example, a width of an upper end of the first connection via 132 may be wider than a width of a lower end of the first connection via 132, in cross-section, and a width of a lower end of the second connection via 133 may be wider than a width of an upper end of the second connection via 133, in cross-section, but the present disclosure is not limited thereto.

The plurality of conductive trenches 141 may pass through the core layer 111, for example, a portion of the core layer 111 from the upper surface of the inorganic substrate 111a. Alternatively, the plurality of conductive trenches 141 may pass through the core layer 111, for example, a portion of the core layer 111 from the lower surface of the inorganic substrate 111a. At least portions of the plurality of conductive trenches 141 may overlap each other in a direction, perpendicular to a trench direction, on a plane. As a result, the capacitor 140 may be formed on the core layer 111. For example, the capacitor 140 may include a deep trench capacitor (DTC). As described, the capacitor 140 may be designed on the core layer 111, as necessary. Thus, the capacitor 140 may not be additionally mounted on the core layer 111.

Hereinafter, components of the printed circuit board 100A according to an example will be described in more detail with reference to the drawings.

The core layer 111 may include the inorganic substrate 111a and the inorganic insulating films 111b-1 and 111b-2. The inorganic substrate 111a may include an inorganic insulating material. The inorganic insulating material may be, for example, silicon or ceramic. For example, the inorganic substrate 111a may be a silicon board or a ceramic board. Silicon may include pure silicon (Si). Ceramics may include, for example, alumina (Al₂O₃), aluminum nitride (AlN), silicon carbide (SiC), silicon nitride (Si₃N₄), or the like, but the present inventive concept is not limited thereto. The inorganic insulating films 111b-1 and 111b-2 may include the oxide film 111b-1 including SiO₂ or the like, and the nitride film 111b-2 including SiN or the like, but the present disclosure is not limited thereto.

The first insulating layer 112 may include an organic insulating material. The organic insulating material may be a thermosetting resin such as an epoxy resin or a thermoplastic resin such as polyimide. An inorganic filler and/or an organic filler may be further included, as necessary. For example, the first insulating layer 112 may include an UR, an EMC, a TIM, or the like, depending on the required properties. However, the present disclosure is not limited thereto, and the first insulating layer 112 may include an organic insulating material the same as those of the second insulating layer 113 and/or the third insulating layer 114 to be described below, as necessary.

The second and third insulating layers 113 and 114 may include an organic insulating material. The organic insulating material may include a thermosetting resin such as an epoxy resin, a thermoplastic resin such as polyimide, or a material including an inorganic filler, an organic filler, and/or a glass fiber (or glass cloth or glass fabric), together with a resin. For example, the organic insulating material may be a non-photosensitive material such as an ABF, a PPG, or the like, but the present disclosure is not limited thereto, and other polymer materials may be used. In addition, the organic insulating material may be a photosensitive insulating material such as photoimageable dielectric (PID) or the like. In addition, the organic insulating material may include an adhesive sheet such as a bonding sheet (BS) or the like.

The first and second wiring layers 121 and 122 may include a metal. The metal may include copper (Cu), aluminum (Al), silver (Ag), tin (Sn), gold (Au), nickel (Ni), lead (Pb), titanium (Ti), and/or alloys thereof, and may preferably include copper (Cu), but the present disclosure is not limited thereto. The first and second wiring layers 121 and 122 may perform various functions depending on a design thereof. For example, the first and second wiring layers 121 and 122 may include a signal pattern, a power pattern, a ground pattern, and the like. Each of the above-described patterns may have various forms such as a line, a plane, a pad, and the like. The first and second wiring layers 121 and 122 may include an electroless plating layer (or chemical copper) and an electrolytic plating layer (or electrolytic copper). Alternatively, the first and second wiring layers 121 and 122 may include a metal foil (or copper foil) and an electrolytic plating layer (or electrolytic copper). Alternatively, the first and second wiring layers 121 and 122 may include a metal foil (or copper foil), an electroless plating layer (or chemical copper), and an electrolytic plating layer (or electrolytic copper). A sputtering layer may be included instead of the electroless plating layer (or chemical copper), and both may be included, as necessary.

The through-via 131 may include a metal. The metal may include at least one selected from the group consisting of copper (Cu), aluminum (Al), silver (Ag), tin (Sn), gold (Au), nickel (Ni), lead (Pb), titanium (Ti), and alloys thereof, and may preferably include copper (Cu), but the present disclosure is not limited thereto. The through-via 131 may pass through a space between the upper surface and the lower surface of the core layer 111. The upper surface and the lower surface of the through-via 131 may be substantially coplanar with the upper surface and the lower surface of the core layer 111, respectively. The through-via 131 may perform various functions depending on a design thereof. For example, the through-via 131 may include a ground via, a power via, a signal via, and the like. The through-via 131 may have an approximately circular or oval shape on a plane, but the present disclosure is not limited thereto. For example, the through-via 131 may have an approximate flower shape on a plane in terms of ensuring close contact by increasing a specific surface area.

The first and second connection vias 132 and 133 may include a metal. The metal may include at least one selected from the group consisting of copper (Cu), aluminum (Al), silver (Ag), tin (Sn), gold (Au), nickel (Ni), lead (Pb), titanium (Ti), and alloys thereof, and may preferably include copper (Cu), but the present disclosure is not limited thereto. The first and second connection vias 132 and 133 may include a filled via filling a via hole, or a conformal via disposed along a wall surface of the via hole. The first and second connection vias 132 and 133 may perform various functions depending on a design thereof. For example, the first and second connection vias 132 and 133 may include a ground via, a power via, a signal via, and the like. The first and second connection vias 132 and 133 may include an electroless plating layer (or chemical copper) and an electrolytic plating layer (or electrolytic copper). A sputtering layer may be included instead of the electroless plating layer (or chemical copper), and both may be included, as necessary.

The capacitor 140 may include a deep trench capacitor (DTC). For example, the capacitor 140 may include a plurality of conductive trenches 141. Each of the plurality of conductive trenches 141 may include a metal. The metal may include at least one selected from the group consisting of copper (Cu), aluminum (Al), silver (Ag), tin (Sn), gold (Au), nickel (Ni), lead (Pb), titanium (Ti), and alloys thereof. The capacitor 140 may be electrically connected to at least a portion of the first wiring layer 121 and/or the second wiring layer 122 through a connection via or the like.

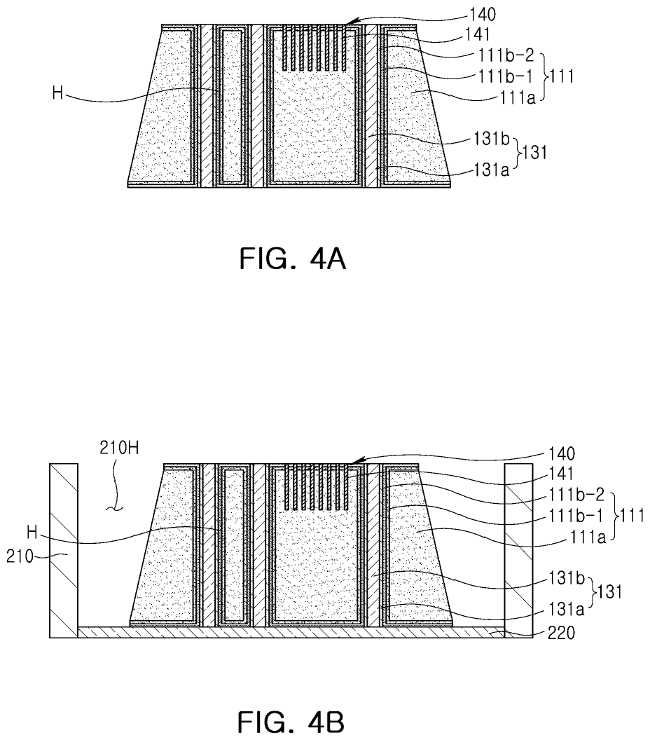

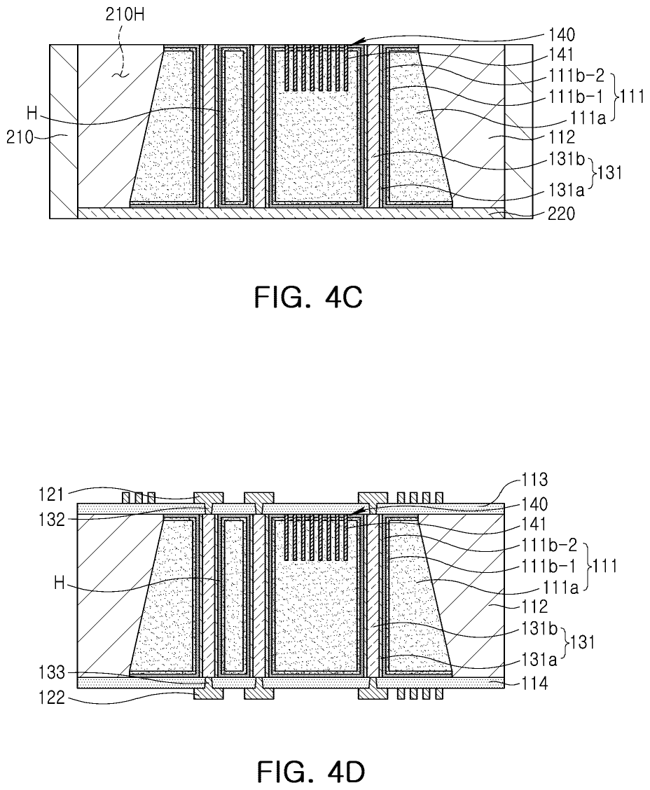

FIGS. 4A to 4D are schematic cross-sectional views of example processes of a method of manufacturing the printed circuit board in FIG. 3.

Referring to FIG. 4A, a core layer 111 in which a one or more through-vias 131 are formed may be prepared. For example, an inorganic substrate 111a including silicon or ceramic may be prepared. Subsequently, one or more through-holes H may be formed in the inorganic substrate 111a using various methods such as laser processing, mechanical processing, chemical processing, and the like. Subsequently, inorganic insulating films 111b-1 and 111b-2 including an oxide film 111b-1 and/or a nitride film 111b-2, respectively, covering a surface of the inorganic substrate 111a and a wall surface of the through-hole H, may be formed using a deposition process, a coating process, or the like. Subsequently, the first metal layer 131a may be formed on the wall surface of the through-holes H using electroless plating or sputtering. Subsequently, a second metal layer 131b, filling at least a portion of the through-holes H, may be formed on the first metal layer 131a using electrolytic plating or the like. A seed layer and/or a plating layer on an upper surface and a lower surface of the core layer 111 may be removed by etching or the like. Subsequently, the core layer 111 in which the through-via 131 is formed may be cut on a unit basis. As a result, a plurality of core layers 111 having inclined external surfaces may be formed on a unit basis. For example, a plurality of core portions may be formed on a unit basis.

Referring to FIG. 4B, the core layer 111 in which the through-vias 131 are formed, the core layer 111 having an inclined external surface may be disposed in a through-hole 210H of a frame 210. For example, an adhesive tape 220 may be attached to a lower side of the frame 210 to block a lower side of the through-hole 210H, and then the core layer 111 in which the through-via 131 is formed may be attached to the tape 220 exposed from the through-hole 210H. The frame 210 may include various materials such as a metal, an organic insulating material, and the like. For example, the frame 210 may have a multilayer board structure formed using copper clad laminate (CCL) or the like, but the present disclosure is not limited thereto. The frame 210 may be in the form of a jig. The tape 220 may be a heat-resistant tape such as polyimide (PI), but the present disclosure is not limited thereto.

Referring to FIG. 4C, a remaining space of the through-hole 210H may be filled with a first insulating layer 112. As a result, the inclined external surface of the core layer 111 may be covered with the first insulating layer 112. In this case, flattening may be performed, as necessary. The first insulating layer 112 may be formed using an underfill process, an encapsulation process, or a lamination process.

Referring to FIG. 4D, the tape 220 may be removed. In addition, second and third insulating layers 113 and 114 may be formed on upper sides and lower sides of the core layer 111 and the first insulating layer 112, respectively, using a lamination process or the like. Subsequently, via holes may be processed in the second and third insulating layers 113 and 114, and then a plating process may be performed to form first and second wiring layers 121 and 122 and first and second connection vias 132 and 133. Subsequently, the frame 210 may be removed. The frame 210 may be removed using a singulation process.

The printed circuit board 100A according to some example embodiments of the present disclosure may be manufactured using a series of processes. Other descriptions may be the same as those of the printed circuit board 100A according to an example, and repeated descriptions thereof will be omitted.

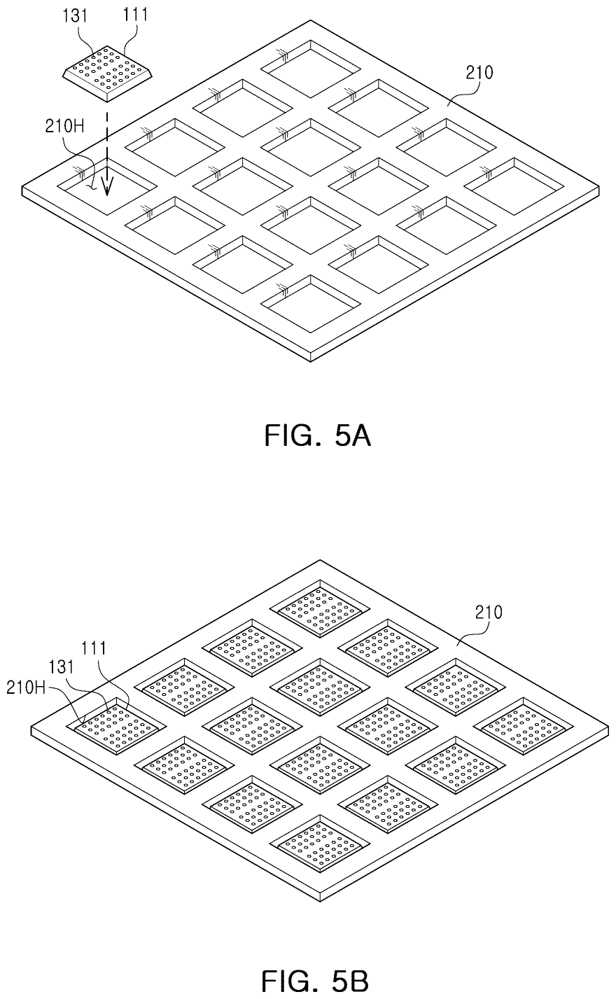

FIGS. 5A and 5B are schematic perspective views of example processes of a case in which a plurality of core portions, provided on a unit basis, are disposed on a frame having a plurality of through-portions.

Referring to FIG. 5A, a frame 210 may have a plurality of through-portions 210H. In the through-portions 210H, core layers 111 cut on a unit basis using the above-described process in FIG. 4B, for example, core portions may be disposed.

Referring to FIG. 5B, the core layers 111 provided on a unit basis in substantially the same form, for example, the core portions, may be disposed in the plurality of through-portions 210H. Thereafter, a plurality of unit boards may be manufactured in the frame 210 using the above-described processes in FIGS. 4C and 4D, and a plurality of printed circuit boards 100A may be obtained using a singulation process.

The printed circuit board 100A according to some example embodiments of the present disclosure may be manufactured using a series of processes. Other descriptions may be the same as those of the printed circuit board 100A according to an example, and repeated descriptions thereof will be omitted.

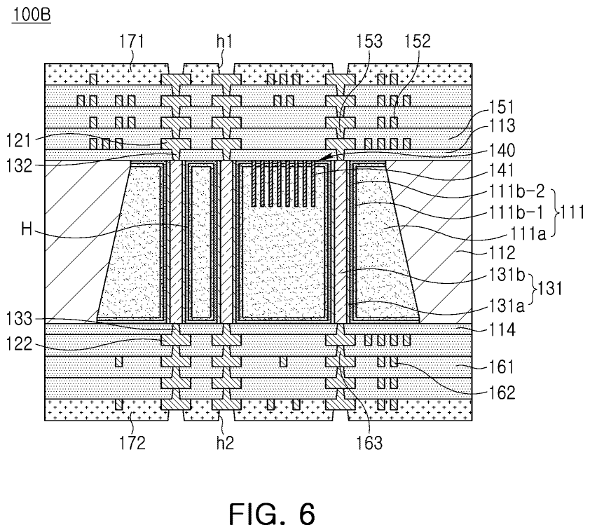

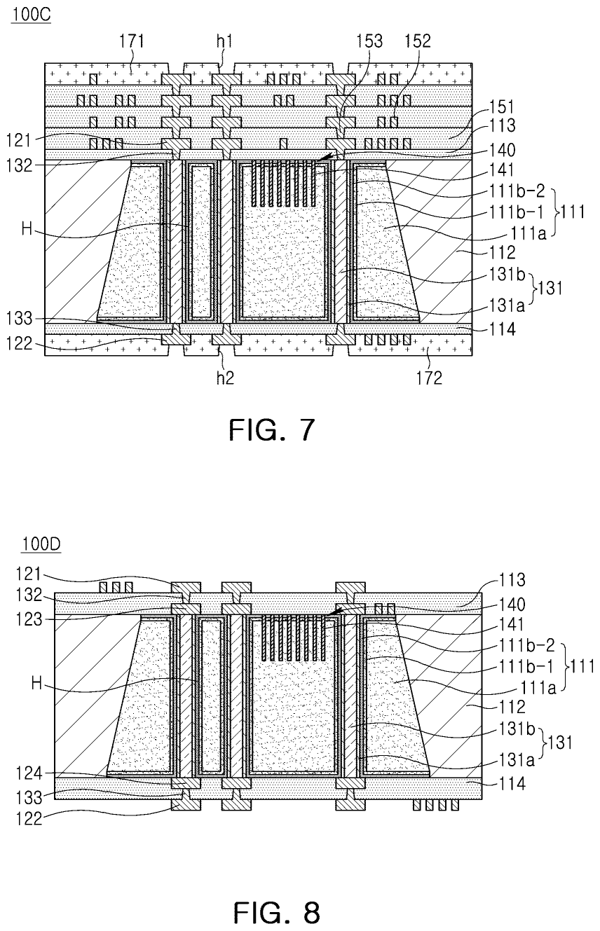

FIGS. 6 and 7 are schematic cross-sectional views of modifications of the printed circuit board in FIG. 3.

Referring to FIG. 6, as compared to the printed circuit board 100A as illustrated above, a printed circuit board 100B according to a modification may further include one or more first build-up insulating layers 151 disposed on an upper surface of a second insulating layer 113, one or more first build-up wiring layers 152 disposed on or in the one or more first build-up insulating layers 151, one or more first build-up via layers 153 passing through at least one of the one or more first build-up insulating layers 151, one or more second build-up insulating layers 161 disposed on a lower surface of a third insulating layer 114, one or more second build-up wiring layers 162 disposed on or in the one or more second build-up insulating layers 161, one or more second build-up via layers 163 passing through at least one of the one or more second build-up insulating layers 161, a first resist layer 171 disposed on an upper surface of an uppermost first build-up insulating layer 151 among the one or more first build-up insulating layers 151, the first resist layer 171 covering at least a portion of an uppermost first build-up wiring layer 152 among the one or more first build-up wiring layers 152, and a second resist layer 172 disposed on a lower surface of a lowermost second build-up insulating layer 161 among the one or more second build-up insulating layers 161, the second resist layer 172 covering at least a portion of a lowermost second build-up wiring layer 162 among the one or more second build-up wiring layers 162. The first resist layer 171 may have a plurality of first openings hl exposing at least a portion of the uppermost first build-up wiring layer 152. The second resist layer 172 may have a plurality of second openings h2 exposing at least a portion of the lowermost second build-up wiring layer 162. As described, the printed circuit board 100B according to a modification may include, as a core board, the printed circuit board 100A according to an example, and may be a multilayer board further including build-up structures on an upper side and a lower side of the core board,. For example, the printed circuit board 100B may be a multilayer board having an approximately symmetrical structure.

Referring to FIG. 7, as compared to the printed circuit board 100A as illustrated above, a printed circuit board 100C according to another modification may further include one or more first build-up insulating layers 151 disposed on an upper surface of a second insulating layer 113, one or more first build-up wiring layers 152 disposed on or in the one or more first build-up insulating layers 151, one or more first build-up via layers 153 passing through at least one of the one or more first build-up insulating layers 151, a first resist layer 171 disposed on an upper surface of an uppermost first build-up insulating layer 151 among the one or more first build-up insulating layers 151, the first resist layer 171 covering at least a portion of an uppermost first build-up wiring layer 152 among the one or more first build-up wiring layers 152, and a second resist layer 172 disposed on a lower surface of a third insulating layer 114, the second resist layer 172 covering at least a portion of a second wiring layer 122. The first resist layer 171 may have a plurality of first openings h1 exposing at least a portion of the uppermost first build-up wiring layer 152. The second resist layer 172 may have a plurality of second openings h2 exposing at least a portion of the second wiring layer 122. As described, the printed circuit board 100C according to another modification may include, as a core board, the printed circuit board 100A according to an example, and may be a multilayer board further including build-up structures on an upper side and a lower side of the core board,. For example, the printed circuit board 100C may be a multilayer board having an asymmetrical structure.

Hereinafter, components of the printed circuit boards 100B and 100C according to modifications will be described in more detail with reference to the drawings.

The one or more first and second build-up insulating layers 151 and 161 may include an insulating material. The insulating material may include a thermosetting resin such as an epoxy resin, a thermoplastic resin such as polyimide, or a material including an inorganic filler, an organic filler, and/or a glass fiber (or glass cloth or glass fabric), together with the above-described resins. The insulating material may be a non-photosensitive insulating material such as an ABF, a PPG, or the like, or may include a photosensitive insulating material such as a PID or the like. In addition, other polymer materials, such as polyimide (PI), a cycloolefinpolymer (COP), and the like, may be used. The one or more first and second build-up insulating layers 151 and 161 may include substantially the same insulating material, but the present disclosure is not limited thereto, and the one or more first and second build-up insulating layers 151 and 161 may include different insulating materials.

The one or more first and second build-up wiring layers 152 and 162 may include a metal. The metal may include copper (Cu), aluminum (Al), silver (Ag), tin (Sn), gold (Au), nickel (Ni), lead (Pb), titanium (Ti), and/or alloys thereof, and may preferably include copper (Cu), but the present disclosure is not limited thereto. The one or more first and second build-up wiring layers 152 and 162 may perform various functions depending on a design thereof. For example, the one or more first and second build-up wiring layers 152 and 162 may include a signal pattern, a power pattern, a ground pattern, and the like. Each of the above-described patterns may have various forms such as a line, a plane, a pad, and the like. The one or more first and second build-up wiring layers 152 and 162 may include an electroless plating layer (or chemical copper) and an electrolytic plating layer (or electrolytic copper). Alternatively, the one or more first and second build-up wiring layers 152 and 162 may include a metal foil (or copper foil) and an electrolytic plating layer (or electrolytic copper). Alternatively, the one or more first and second build-up wiring layers 152 and 162 may include a metal foil (or copper foil), an electroless plating layer (or chemical copper), and an electrolytic plating layer (or electrolytic copper). A sputtering layer may be included instead of the electroless plating layer (or chemical copper), and both may be included, as necessary.

The one or more first and second build-up via layers 153 and 163 may include a metal. The metal may include at least one selected from the group consisting of copper (Cu), aluminum (Al), silver (Ag), tin (Sn), gold (Au), nickel (Ni), lead (Pb), titanium (Ti), and alloys thereof, and may preferably include copper (Cu), but the present disclosure is not limited thereto. The one or more first and second build-up via layers 153 and 163 may include a filled via filling a via hole, or a conformal via disposed along a wall surface of the via hole. The one or more first and second build-up via layers 153 and 163 may perform various functions depending on a design thereof. For example, the one or more first and second build-up via layers 153 and 163 may include a ground via, a power via, a signal via, and the like. In cross-section, each of the one or more first build-up via layers 153 may have a tapered shape in a direction opposite to that of each of the one or more second build-up via layers 163. The one or more first and second build-up via layers 153 and 163 may include an electroless plating layer (or chemical copper) and an electrolytic plating layer (or electrolytic copper). A sputtering layer may be included instead of the electroless plating layer (or chemical copper), and both may be included, as necessary.

The first and second resist layers 171 and 172 may include a liquid-type solder resist or a film-type solder resist, but are not limited thereto, and other types of insulating materials, such as an ABF and the like, may also be used. A surface treatment layer may be formed on each of patterns exposed through the plurality of first and second openings h1 and h2, as necessary. The surface treatment layer may be formed using electrolytic gold plating, electroless gold plating, organic solderability preservative (OSP) or electroless tin plating, electroless silver plating, electroless nickel plating/substituted gold plating, direct immersion gold (DIG) plating, hot air solder leveling (HASL), or the like, but the present disclosure is not limited thereto. Alternatively, a metal bump may be formed on each of the patterns exposed through the plurality of first and second openings h1 and h2, as necessary. The metal bump may include an under-bump metal (UBM), but the present disclosure is not limited thereto.

The printed circuit board 100A according to an example may be manufactured using a series of processes. Other descriptions may be the same as those of the printed circuit board 100A according to an example, and repeated descriptions thereof will be omitted.

FIG. 8 is a schematic cross-sectional view of another example of a printed circuit board.

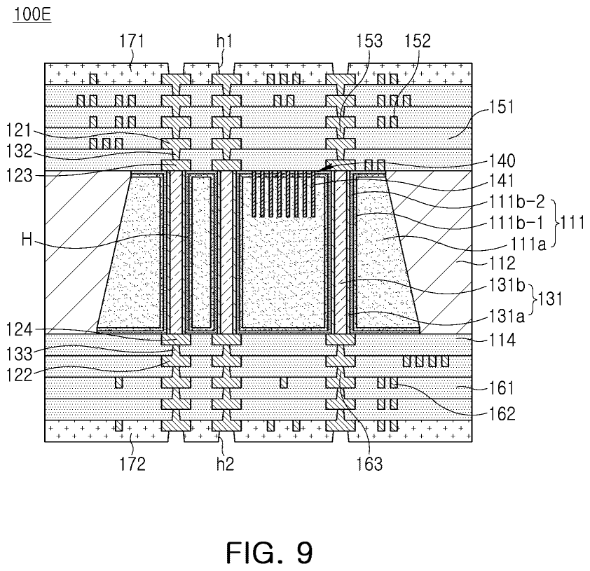

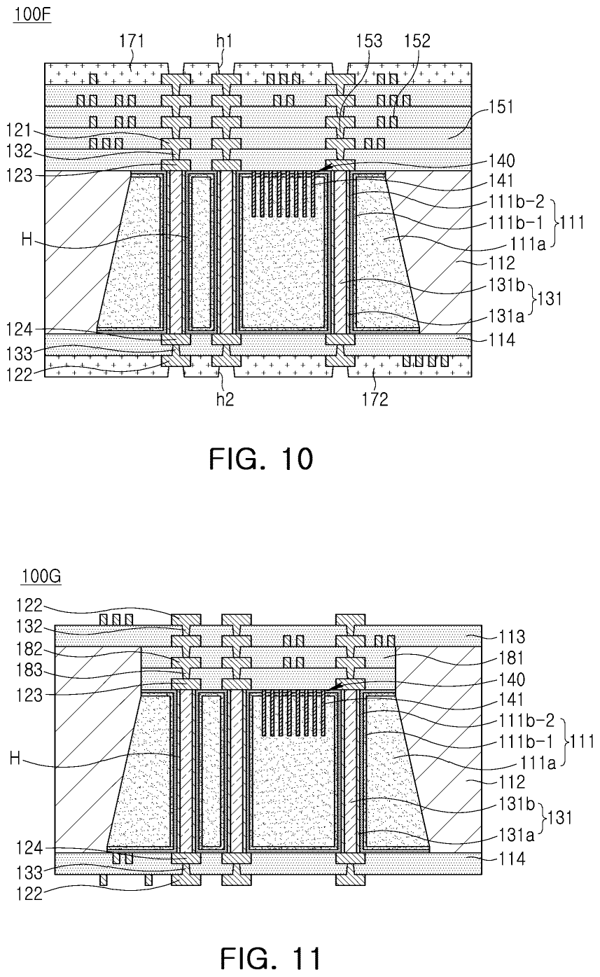

FIGS. 9 and 10 are schematic cross-sectional views of modifications of the printed circuit board in FIG. 8.

Referring to FIGS. 8 to 10, as compared to the printed circuit boards 100A, 100B and 100C illustrated above, a printed circuit board 100D according to another example and printed circuit boards 100E and 100F according to modifications thereof may further include a core layer 111, for example, a third wiring layer 123 disposed on an upper surface of an inorganic substrate 111a and connected to a through-via 131, the third wiring layer 123 having at least a portion buried in a second insulating layer 113, and a core layer 111, for example, a fourth wiring layer 124 disposed on a lower surface of the inorganic substrate 111a and connected to the through-via 131, the fourth wiring layer 124 having at least a portion buried in a third insulating layer 114. A first connection via 132 may pass through the second insulating layer 113 to connect the first and third wiring layers 121 and 123 to each other. A second connection via 133 may pass through the third insulating layer 114 to connect the second and fourth wiring layers 122 and 124 to each other. As described, the printed circuit board 100D according to another example and the printed circuit boards 100E and 100F according to modifications thereof may further include the core layers 111, for example, the third and fourth wiring layers 123 and 124 respectively disposed on the upper and lower surfaces of the inorganic substrate 111a, the third and fourth wiring layers 123 and 124 in direct contact with the through-via 131. As a result, a wiring may be more diversely designed. For example, a degree of design freedom may be increased.

Hereinafter, components of the printed circuit board 100D according to another example and the printed circuit boards 100E and 100F according to modifications thereof will be described in more detail with reference to the drawings.

The third and fourth wiring layers 123 and 124 may include a metal. The metal may include at least one selected from the group consisting of copper (Cu), aluminum (Al), silver (Ag), tin (Sn), gold (Au), nickel (Ni), lead (Pb), titanium (Ti), and alloys thereof, and may preferably include copper (Cu), but the present disclosure is not limited thereto. The third and fourth wiring layers 123 and 124 may perform various functions depending on a design thereof. For example, the third and fourth wiring layers 123 and 124 may include a signal pattern, a power pattern, a ground pattern, and the like. Each of the above-described patterns may have various forms such as a line, a plane, a pad, and the like. The third and fourth wiring layers 123 and 124 may include an electroless plating layer (or chemical copper) and an electrolytic plating layer (or electrolytic copper). Alternatively, the third and fourth wiring layers 123 and 124 may include a metal foil (or copper foil) and an electrolytic plating layer (or electrolytic copper). Alternatively, the third and fourth wiring layers 123 and 124 may include a metal foil (or copper foil), an electroless plating layer (or chemical copper), and an electrolytic plating layer (or electrolytic copper). A sputtering layer may be included instead of the electroless plating layer (or chemical copper), and both may be included, as necessary.

Other descriptions may be the same as those of the printed circuit board 100A according to an example and the printed circuit boards 100B and 100C according to modifications thereof, and repeated descriptions thereof will be omitted.

FIG. 11 is a schematic cross-sectional view of another example of a printed circuit board.

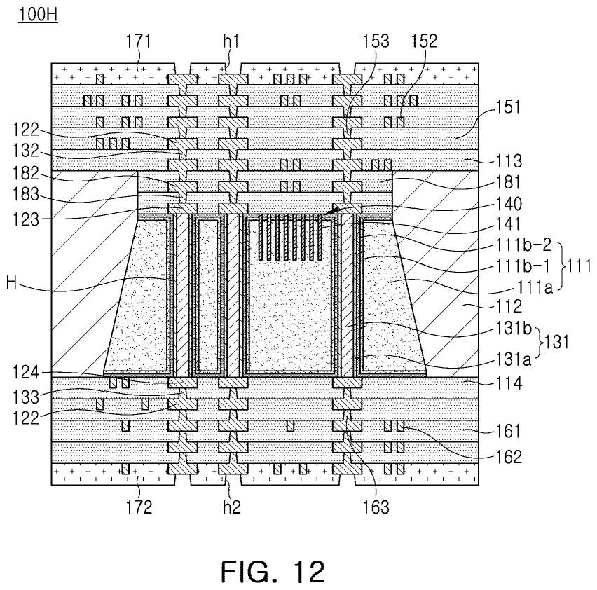

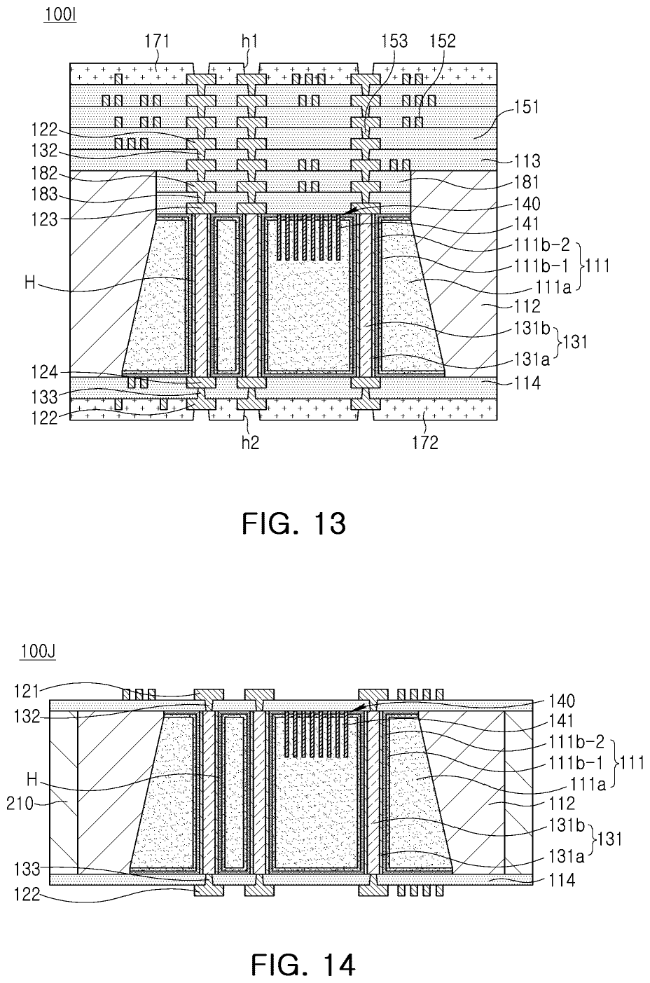

FIGS. 12 and 13 are schematic cross-sectional views of modifications of the printed circuit board in FIG. 11.

Referring to FIGS. 11 to 13, as compared to the printed circuit board 100D according to another example and the printed circuit boards 100E and 100F according to modifications thereof, a printed circuit board 100G according to another example and printed circuit boards 100H and 100I according to modifications thereof may further include one or more intermediate insulating layers 181 disposed between a core layer 111 and a second insulating layer 113, for example, between an inorganic substrate 111a and the second insulating layer 113, one or more intermediate wiring layers 182 disposed on or in the one or more intermediate insulating layers 181, and one or more intermediate via layers 183 passing through at least one of the one or more intermediate insulating layers 181. The first insulating layer 112 may further cover at least a portion of an external surface of each of the one or more intermediate insulating layers 181. As described, in the printed circuit board 100G according to another example and the printed circuit boards 100H and 100I according to modifications thereof, an intermediate build-up structure may be further formed on the core layer 111, for example, the inorganic substrate 111a. For example, the above-described core units, provided on a unit basis, may further include an intermediate build-up structure, and may be disposed in a through-portion of the above-described frame in a state in which the intermediate build-up structure is formed. As a result, a wiring may be more diversely designed. For example, a degree of design freedom may be increased.

Hereinafter, components of the printed circuit board 100G according to another example and the printed circuit boards 100H and 100I according to modifications thereof will be described in more detail with reference to the drawings.

The one or more intermediate insulating layers 181 may include an insulating material. The insulating material may include a thermosetting resin such as an epoxy resin, a thermoplastic resin such as polyimide, or a material including an inorganic filler, an organic filler, and/or a glass fiber (or glass cloth or glass fabric), together with the above-described resins. The insulating material may be a non-photosensitive insulating material such as an ABF, a PPG, or the like, or may include a photosensitive insulating material such as a PID or the like. In addition, other polymer materials, such as polyimide (PI), a cycloolefinpolymer (COP), and the like, may be used. The one or more intermediate insulating layers 181 may include substantially the same insulating material, but the present disclosure is not limited thereto, and the one or more intermediate insulating layers 181 may include different insulating materials.

The one or more intermediate wiring layers 182 may include a metal. The metal may include 36 copper (Cu), aluminum (Al), silver (Ag), tin (Sn), gold (Au), nickel (Ni), lead (Pb), titanium (Ti), and alloys thereof, and may preferably include copper (Cu), but the present disclosure is not limited thereto. The one or more intermediate wiring layers 182 may perform various functions depending on a design thereof. For example, the one or more intermediate wiring layers 182 may include a signal pattern, a power pattern, a ground pattern, and the like. Each of the above-described patterns may have various forms such as a line, a plane, a pad, and the like. The one or more intermediate wiring layers 182 may include an electroless plating layer (or chemical copper) and an electrolytic plating layer (or electrolytic copper). Alternatively, the one or more intermediate wiring layers 182 may include a metal foil (or copper foil) and an electrolytic plating layer (or electrolytic copper). Alternatively, the one or more intermediate wiring layers 182 may include a metal foil (or copper foil), an electroless plating layer (or chemical copper), and an electrolytic plating layer (or electrolytic copper). A sputtering layer may be included instead of the electroless plating layer (or chemical copper), and both may be included, as necessary.

The one or more intermediate via layers 183 may include a metal. The metal may include at least one selected from the group consisting of copper (Cu), aluminum (Al), silver (Ag), tin (Sn), gold (Au), nickel (Ni), lead (Pb), titanium (Ti), and alloys thereof, and may preferably include copper (Cu), but the present disclosure is not limited thereto. The one or more intermediate via layers 183 may perform various functions depending on a design thereof. For example, the one or more intermediate via layers 183 may include a signal pattern, a power pattern, a ground pattern, and the like. Each of the above-described patterns may have various forms such as a line, a plane, a pad, and the like. The one or more intermediate via layers 183 may include an electroless plating layer (or chemical copper) and an electrolytic plating layer (or electrolytic copper). Alternatively, the one or more intermediate via layers 183 may include a metal foil (or copper foil) and an electrolytic plating layer (or electrolytic copper). Alternatively, the one or more intermediate via layers 183 may include a metal foil (or copper foil), an electroless plating layer (or chemical copper), and an electrolytic plating layer (or electrolytic copper). A sputtering layer may be included instead of the electroless plating layer (or chemical copper), and both may be included, as necessary.

Other descriptions may be the same as those of the printed circuit board 100A according to an example and the printed circuit boards 100B and 100C according to modifications thereof, and the printed circuit board 100D according to another example and the printed circuit boards 100E and 100F according to modifications thereof, and repeated descriptions thereof will be omitted.

FIG. 14 is a schematic cross-sectional view of another example of a printed circuit board.

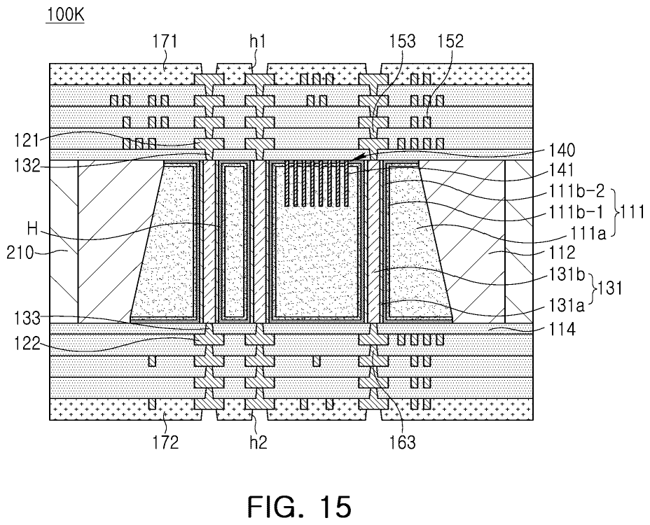

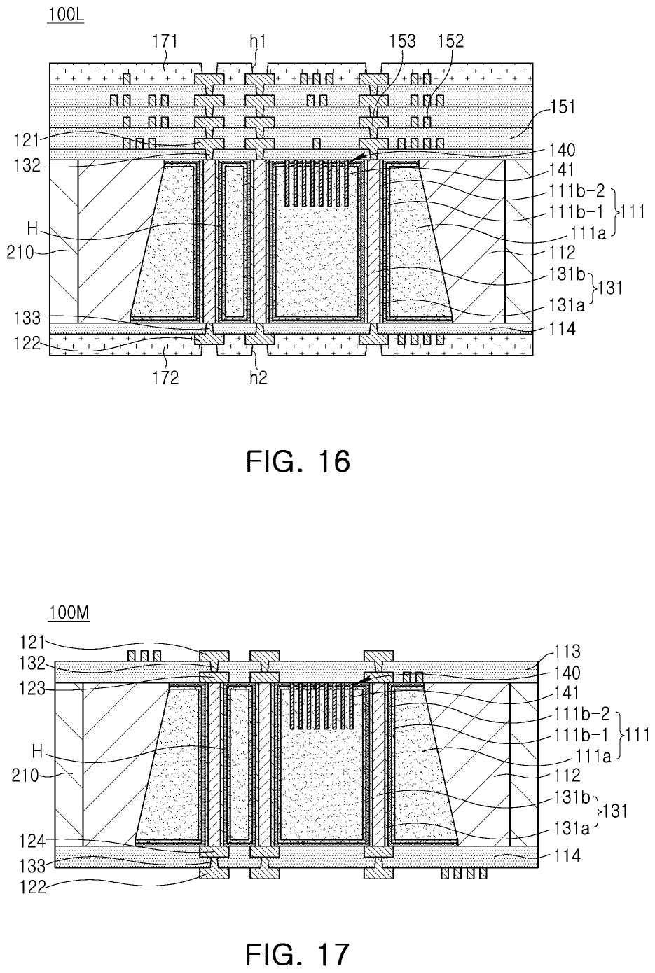

FIGS. 15 and 16 are schematic cross-sectional views of modifications of the printed circuit board in FIG. 14.

Referring to FIGS. 14 to 16, as compared to the printed circuit board 100A according to an example and the printed circuit boards 100B and 100C according to modifications thereof, a printed circuit board 100J according to another example and printed circuit boards 100K and 100L according to modifications thereof may further include a frame 210 covering at least a portion of an external surface of a first insulating layer 112. A second insulating layer 113 may be disposed to further extend to an upper side of the frame 210. For example, the second insulating layer 113 may further cover at least a portion of an upper surface of the frame 210. A third insulating layer 114 may be disposed to further extend to a lower side of the frame 210. For example, the third insulating layer 114 may further cover at least a portion of a lower surface of the frame 210. The frame 210 may be disposed to continuously surround the approximately entire external surface of the first insulating layer 112, and the first insulating layer 112 may be disposed to continuously surround the approximately entire external surface of a core layer 111. As described, for board properties or warpage control, a singulation process may be performed, such that the frame 210, used as a jig in the above-described process, may remain on an outermost side. As a result, the printed circuit board according to another example 100J and the printed circuit boards 100K and 100L according to modifications thereof may further include the frame 210, covering at least a portion of the external surface of the first insulating layer 112.

Other descriptions may be the same as those of the printed circuit board 100A, the printed circuit boards 100B and 100C according to modifications thereof, and repeated descriptions thereof will be omitted.

FIG. 17 is a schematic cross-sectional view of another example of a printed circuit board.

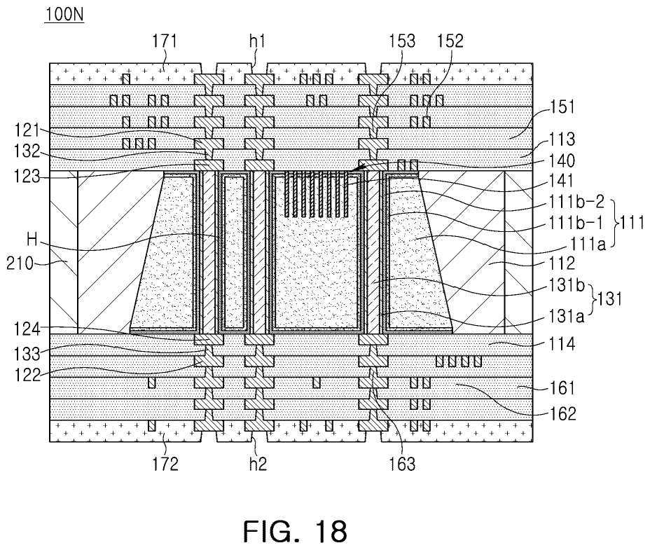

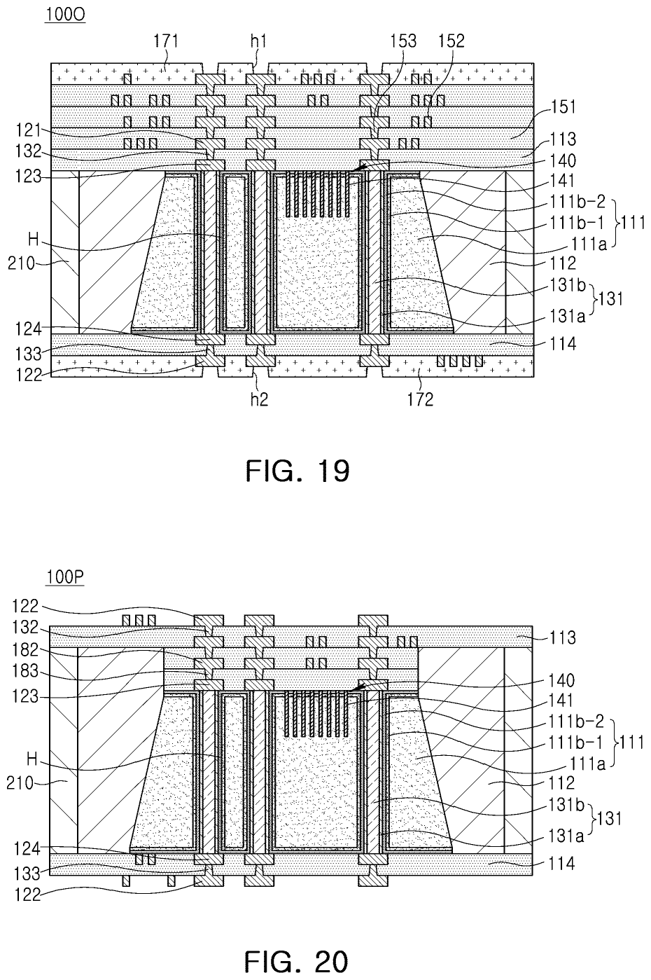

FIGS. 18 and 19 are schematic cross-sectional views of modifications of the printed circuit board in FIG. 17.

Referring to FIGS. 17 to 19, as compared to the printed circuit board 100D according to another example and the printed circuit boards 100E and 100F according to modifications thereof, a printed circuit board 100M according to another example and printed circuit boards 100N and 100O according to modifications thereof may further include a frame 210 covering at least a portion of an external surface of a first insulating layer 112. A second insulating layer 113 may be disposed to further extend to an upper side of the frame 210. For example, the second insulating layer 113 may further cover at least a portion of an upper surface of the frame 210. A third insulating layer 114 may be disposed to further extend to a lower side of the frame 210. For example, the third insulating layer 114 may further cover at least a portion of a lower surface of the frame 210. The frame 210 may be disposed to continuously surround the approximately entire external surface of the first insulating layer 112, and the first insulating layer 112 may be disposed to continuously surround the entire approximately external surface of a core layer 111. As described, for board properties or warpage control, a singulation process may be performed, such that the frame 210, used as a jig in the above-described process, may remain on an outermost side. As a result, the printed circuit board according to another example 100M and the printed circuit boards 100N and 100O according to modifications thereof may further include the frame 210, covering at least a portion of the external surface of the first insulating layer 112.

Other descriptions may be the same as those of the printed circuit board 100A according to an example and the printed circuit boards 100B and 100C according to modifications thereof, and the printed circuit board 100D according to another example and the printed circuit boards 100E and 100F according to modifications thereof, and repeated descriptions thereof will be omitted.

FIG. 20 is a schematic cross-sectional view of another example of a printed circuit board.

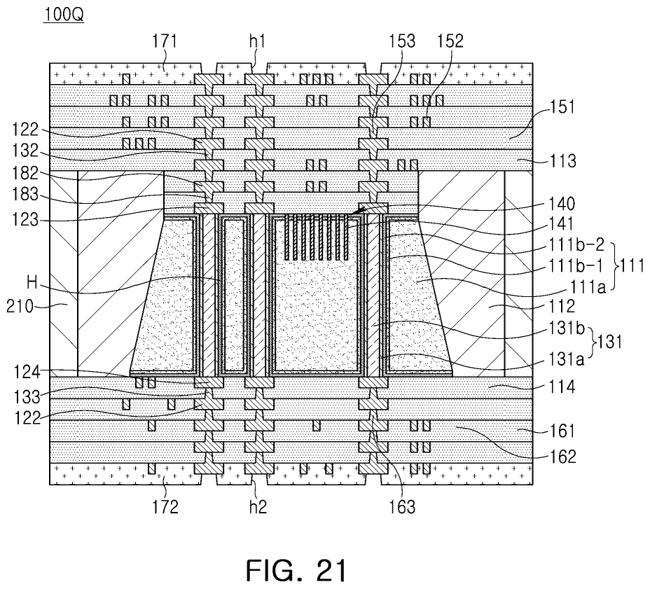

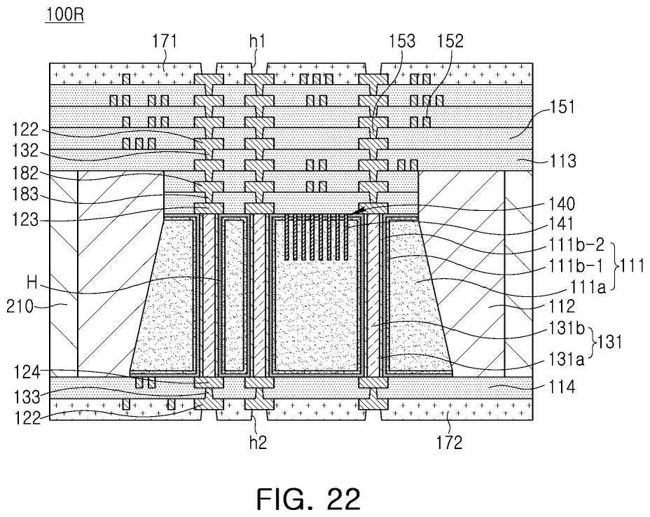

FIGS. 21 and 22 are schematic cross-sectional views of modifications of the printed circuit board in FIG. 20.

Referring to FIGS. 20 to 22, as compared to the printed circuit board 100G according to another example and the printed circuit boards 100H and 100I according to modifications thereof, a printed circuit board 100P according to another example and printed circuit boards 100Q and 100R according to modifications thereof may further include a frame 210 covering at least a portion of an external surface of a first insulating layer 112. A second insulating layer 113 may be disposed to further extend to an upper side of the frame 210. For example, the second insulating layer 113 may further cover at least a portion of an upper surface of the frame 210. A third insulating layer 114 may be disposed to further extend to a lower side of the frame 210. For example, the third insulating layer 114 may further cover at least a portion of a lower surface of the frame 210. The frame 210 may be disposed to continuously surround the approximately entire external surface of the first insulating layer 112, and the first insulating layer 112 may be disposed to continuously surround the approximately entire external surface of the core layer 111. As described, for board properties or warpage control, a singulation process may be performed, such that the frame 210, used as a jig in the above-described process, may remain on an outermost side. As a result, the printed circuit board according to another example 100P and the printed circuit boards 100Q and 100R according to modifications thereof may further include the frame 210, covering at least a portion of the external surface of the first insulating layer 112.

Other descriptions may be the same as those of the printed circuit board 100A according to an example and the printed circuit boards 100B and 100C according to modifications thereof, and the printed circuit board 100G according to another example and the printed circuit boards 100H and 100I according to modifications thereof, and repeated descriptions thereof will be omitted.

As used herein, the terms “cover,” “to cover,” and “covering” may include entirely covering as well as at least partially covering, and may include directly covering as well as indirectly covering. In addition, the terms “fill,” to fill,” and “filling” may include not only entirely filling, but also approximately filling, for example, may include a case in which some voids, pores or the like are present. In addition, the terms “surround,” “to surround,” and “surrounding” may include not only entirely surrounding but also approximately surrounding. In addition, exposing may include not only entirely exposing but also exposing at least a portion of a structure, and exposure may mean exposing a component from another component in which the component is buried. For example, an opening, exposing a pad, may mean exposing the pad from a resist layer, and a surface treatment layer may be further disposed on the exposed pad.

As used herein, a process error or a positional deviation occurring in a manufacturing process, an error in measurement, and the like may be included. For example, “substantially perpendicular” may include not only “completely perpendicular,” but also “approximately perpendicular.” In addition, “substantially coplanar” may include not only “completely coplanar,” but also “approximately coplanar.”

As used herein, the same insulating material may mean not only the exact same insulating material, but also the same type of insulating material. Thus, compositions of insulating materials may be substantially the same, but specific composition ratios thereof may slightly vary.

As used herein, a cross-sectional shape may refer to a cross-sectional shape of an object when the object is vertically cut, or a cross-sectional shape of the object when the object is viewed in a side-view. In addition, a shape on a plane may be a shape of the object when the object is horizontally cut, or a planar shape of the object when the object is viewed in a top-view or a bottom-view.

As used herein, an upper side, an upper portion, the upper surface, or the like is used to refer to a direction toward a surface on which an electronic component is mountable based on a cross-section of a drawing for ease, and a lower side, a lower portion, a lower surface, or the like is used to refer to an opposite direction thereof. However, the above-described directions are defined for ease of description. Thus, it should be understood that the scope of the claims is not particularly limited by the above-described directions, and the concepts of “upper” and “lower” may change at any time.

As used herein, the term “connected” may not only refer to “directly connected” but also include “indirectly connected” by means of an adhesive layer, or the like. The term “electrically connected” may include both of a case in which components are “physically connected” and a case in which components are “not physically connected.” In addition, the terms “first,” “second,” and the like may be used to distinguish a component from another component, and may not limit a sequence and/or an importance, or others, in relation to the components. In some cases, a first component may be referred to as a second component, and similarly, a second component may be referred to as a first component without departing from the scope of the example embodiments.

As used herein, thickness, width, length, and depth may be measured using a scanning microscope or an optical microscope based on a cross-section obtained by polishing or cutting a printed circuit board. The cross-section may be a vertical cross-section or a horizontal cross-section, and each value may be measured based on the required cross-section. When the value is not constant, the value may be determined as an average value of values measured at five arbitrary points.

As used herein, the term “an example embodiment” or “some example embodiments” is provided to emphasize a particular feature, structure, or characteristic, and do not necessarily refer to the same example embodiment. In addition, the particular characteristics or features may be combined in any suitable manner in one or more example embodiments. For example, a context described in a specific example embodiment may be used in other example embodiments, even if it is not described in the other example embodiments, unless it is described contrary to or inconsistent with the context in the other example embodiments.

The terms used herein describe particular example embodiments only, and the present disclosure is not limited thereby. As used herein, singular forms “a,” “an,” and “the” are intended to include the plural forms as well, unless the context clearly indicates otherwise.

As used herein, the term “substantially” means a small, insignificant amount from absolute or perfect conditions, dimensions, measurements, results, etc., would be expected by one skilled in the art, but which does not significantly affect overall performance and allow for variation. “Substantially” when used for a number or parameter or property that can be expressed as a number means within 10 percent

While example embodiments have been shown and described above, it will be apparent to those skilled in the art that modifications and variations could be made without departing from the scope of the present disclosure as defined by the appended claims.

What is claimed is:

1. A printed circuit board comprising:
an inorganic substrate;
a through-via passing through the inorganic substrate;
a first insulating layer covering at least a portion of an external surface of the inorganic substrate which is not upper or lower surface of the inorganic substrate;
a second insulating layer disposed on the upper surface of the inorganic substrate and an upper surface of the first insulating layer;
a third insulating layer disposed on the lower surface of the inorganic substrate and a lower surface of the first insulating layer;
a first wiring layer disposed on a portion of an upper surface of the second insulating layer; and
a second wiring layer disposed on a portion of a lower surface of the third insulating layer,
wherein the inorganic substrate includes silicon or ceramic, and
the inorganic substrate has an upper end and a lower end having different widths, in cross-section.

2. The printed circuit board of claim 1, wherein
the width of the upper end of the inorganic substrate is narrower than the width of the lower end of the inorganic substrate, in cross-section, and
the external surface of the inorganic substrate is substantially inclined.

3. The printed circuit board of claim 1, further comprising:
an inorganic insulating film covering at least a portion of each of the upper surface and the lower surface of the inorganic substrate,
wherein the external surface of the inorganic substrate is spaced apart from the inorganic insulating film, and
the external surface of the inorganic substrate is in contact with the first insulating layer.

4. The printed circuit board of claim 3, wherein the inorganic insulating film includes an oxide film disposed on the inorganic substrate, and a nitride film disposed on the oxide film.

5. The printed circuit board of claim 3, wherein
the inorganic substrate has a through-hole in which the through-via is disposed, and
the inorganic insulating film extends to a space between the inorganic substrate and the through-via to further cover at least a portion of a wall surface of the through-hole.

6. The printed circuit board of claim 5, wherein
the through-via includes a first metal layer disposed on the inorganic insulating film in the through-hole, and a second metal layer filling at least a portion of the through-hole, on the first metal layer, the second metal layer having a width wider than that of the first metal layer, in cross-section.

7. The printed circuit board of claim 1, wherein the first to third insulating layers include an organic insulating material.

8. The printed circuit board of claim 7, wherein
the first insulating layer has an interlayer boundary with each of the second insulating layer and the third insulating layer, and
the upper surface and the lower surface of the first insulating layer are substantially coplanar with the upper surface and the lower surface of the inorganic substrate, respectively.

9. The printed circuit board of claim 7, wherein the first insulating layer is integrated with at least one of the second insulating layer or the third insulating layer without an interlayer boundary.

10. The printed circuit board of claim 1, further comprising:
a first connection via passing through the second insulating layer, the first connection via connecting the through-via and the first wiring layer to each other; and
a second connection via passing through the third insulating layer, the second connection via connecting the through-via and the second wiring layer to each other.

11. The printed circuit board of claim 1, further comprising:
a third wiring layer disposed on the upper surface of the inorganic substrate, connected to the through-via, and at least partially buried in the second insulating layer;
a fourth wiring layer disposed on the lower surface of the inorganic substrate, connected to the through-via, and at least partially buried in the third insulating layer;
a first connection via passing through the second insulating layer, the first connection via connecting the first wiring layer and the third wiring layer to each other; and
a second connection via passing through the third insulating layer, the second connection via connecting the second wiring layer and the fourth wiring layer to each other.

12. The printed circuit board of claim 11, further comprising:
one or more intermediate insulating layers disposed between the inorganic substrate and the second insulating layer;
one or more intermediate wiring layers disposed on or in the one or more intermediate insulating layers; and
one or more intermediate via layers passing through at least one of the one or more intermediate insulating layers,
wherein the first insulating layer further covers at least a portion of an external surface of each of the one or more intermediate insulating layers.

13. The printed circuit board of claim 1, further comprising:
one or more first build-up insulating layers disposed on an upper surface of the second insulating layer;
one or more first build-up wiring layers disposed on or in the one or more first build-up insulating layers;
one or more first build-up via layers passing through at least one of the one or more first build-up insulating layers;
one or more second build-up insulating layers disposed on the lower surface of the third insulating layer;
one or more second build-up wiring layers disposed on or in the one or more second build-up insulating layers;
one or more second build-up via layers passing through at least one of the one or more second build-up insulating layers;
a first resist layer disposed on an upper surface of an uppermost first build-up insulating layer among the one or more first build-up insulating layers, the first resist layer covering at least a portion of an uppermost first build-up wiring layer among the one or more first build-up wiring layers; and
a second resist layer disposed on a lower surface of a lowermost second build-up insulating layer among the one or more second build-up insulating layers, the second resist layer covering at least a portion of a lowermost second build-up wiring layer among the one or more second build-up wiring layers,
wherein the first resist layer has a plurality of first openings exposing at least a portion of the uppermost first build-up wiring layer, and
the second resist layer has a plurality of second openings exposing at least a portion of the lowermost second build-up wiring layer.

14. The printed circuit board of claim 1, further comprising:
one or more first build-up insulating layers disposed on an upper surface of the second insulating layer;
one or more first build-up wiring layers disposed on or in the one or more first build-up insulating layers;
one or more first build-up via layers passing through at least one of the one or more first build-up insulating layers;
a first resist layer disposed on an upper surface of an uppermost first build-up insulating layer among the one or more first build-up insulating layers, the first resist layer covering at least a portion of an uppermost first build-up wiring layer among the one or more first build-up wiring layers; and
a second resist layer disposed on the lower surface of the third insulating layer, the second resist layer covering at least a portion of the second wiring layer,
wherein the first resist layer has a plurality of first openings exposing at least a portion of the uppermost first build-up wiring layer, and
the second resist layer has a plurality of second openings exposing at least a portion of the second wiring layer.

15. The printed circuit board of claim 1, further comprising:
a frame covering at least a portion of an external surface of the first insulating layer,
wherein the second insulating layer is disposed to extend further onto an upper surface of the frame, and
the third insulating layer is disposed to extend further onto a lower surface of the frame.

16. The printed circuit board of claim 1, further comprising:
a capacitor including a plurality of conductive trenches passing through a portion of the inorganic substrate from the upper surface or the lower surface of the inorganic substrate.
